(19) United States
(12) Patent Application Publication
(10) Pub. No.: US 2003/0098491 A1
(43) Pub. Date: May 29, 2003

(54) Semiconductor device with trench isolation and fabrication method thereof

(75) Inventor: Toshiaki Tsutsumi, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/153,625

(22) Filed: May 24, 2002

(30) Foreign Application Priority Data
Nov. 26, 2001 (JP) 2001-359333(P)

(51) Int. Cl. H01L 29/00

(52) U.S. Cl. 257/506

(57) ABSTRACT

It is a main object to provide a semiconductor device with trench isolation, improved so as to be capable of not only relaxing a stress but also forming a channel cut layer under good control to thereby achieve a good isolation characteristic. A trench is formed in a semiconductor substrate at and below a surface thereof. An insulating film, part of which fills the interior of the trench so as to be capable of forming a void in the interior of the trench, and extending above. A diameter of the top end of the trench is smaller than a diameter of the insulating film.

### BACKGROUND OF THE INVENTION

1. Field of the Invention

The present invention generally relates to a semiconductor device with trench isolation, and more particularly, to a semiconductor device with trench isolation, improved so as to be capable of not only relaxing a stress but also achieving a good isolation characteristic. The present invention further relates to a fabrication method of a semiconductor device with such trench isolation.

2. Description of the Background Art

Miniaturization of a semiconductor device has been progressed, which produces a strong demand for element isolation for isolating elements such as transistors. In recent years, as an element isolation technique, a technique has been in use that is called a shallow trench isolation forming a trench in a semiconductor substrate. There is an expectation that a width of an isolation region will be 100 nm or less. While trenches formed in a substrate have been filled with a silicon oxide film as an isolation insulating film, there has been arisen a requirement for a filling technique at a high level with reduction in trench width. With a trend toward a narrower isolation width, a device with an isolation width of 100 nm or less will have progressively increasing difficulty in filling an insulating film in trenches.

Description will be given of a conventional fabrication method below.

Referring to FIG. 40, a silicon oxide film 102 is formed on a semiconductor substrate 101 to a thickness, for example, in the range of 10 to 20 nm by a thermal oxidation method or a CVD (Chemical Vapor Deposition) method. Then, a silicon nitride film 103 is formed to a thickness, for example, in the range of 100 to 200 nm by a CVD method. Thereafter, silicon nitride film 103 and silicon oxide film 102 are patterned by a photolithographic technique and an etching method.

Referring to FIG. 41, semiconductor substrate 101 is etched with silicon nitride film 103 and silicon oxide film 102 as a mask to form a trench 104 of a depth in the range of 100 to 300 nm.

Referring to FIG. 42, a thermal oxide film 105 is formed on a surface of trench 104 to a thickness, for example, in the range of 10 to 20 nm by a thermal oxidation method. Thereafter, a silicon oxide film 106 is formed to a thickness, for example, in the range of 500 to 1000 nm to fill trench 104 by a CVD method, for example a high density plasma CVD method. At this time, when a width of trench 4 is smaller, difficulty comes up in the filling and for example, when a width is 100 nm or less, a void 107 is, in a case, formed under a non-optimized condition.

Referring to FIGS. 42 and 43, silicon oxide film 106 is polished while planarizing by a CMP (Chemical Mechanical Polish) method to expose silicon nitride film 103. In this step, silicon oxide film 106 is formed only in the top portion of trench 104.

Referring to FIG. 44, silicon oxide film 106 is etched to cause the uppermost surface thereof to be flush with a surface of semiconductor substrate 101.

Referring to FIG. 45, silicon nitride film 103 and silicon oxide film 102 are etched off to leave silicon oxide film 106 only in trench 104 and to thus form element isolation.

Referring to FIG. 46, thereafter, a gate oxide film 108 is formed by a well known process, for example by a thermal oxidation method, a gate electrode 109 is formed, a first impurity diffusion layer 110 is formed, a sidewall spacer 111 is formed, a second impurity diffusion layer 112 is formed and a MOSFET (Metal-Oxide-Semiconductor Field Effect Transistor) is thus completed.

While a prior art semiconductor device is fabricated by a method as described above, referring to FIG. 46, when a void is formed, a recess occurs on the surface of silicon oxide film 106 filling trench 104 for element isolation and etching residue during formation of gate electrode is produced in the recess. The etching residue 113 frequently causes, for example, unnecessary short-circuit between gate electrodes, leading to a problem of increasing a fraction defective of integrated circuits to thereby decrease a yield thereof.

Furthermore, by a difference in thermal expansion coefficient between a silicon oxide film filling a trench and silicon of a semiconductor substrate, a thermal stress is produced to deteriorate an electrical characteristic. In a case where a void is formed in a trench to relax a stress, it is difficult to control a shape of a void to be constant and to form a channel cut implanted layer.

### SUMMARY OF THE INVENTION

The present invention has been made in order to solve the above problem and it is an object of the present invention to provide a semiconductor device having trench isolation, improved so as to be capable of preventing unnecessary short-circuit between gate electrodes.

It is another object of the present invention to provide a semiconductor device having trench isolation improved so as to be capable of relaxing a stress.

A semiconductor device according to the first aspect of the invention includes a semiconductor substrate. A trench is provided on a surface of the semiconductor substrate. An insulating film that a part thereof fits into the trench so as to form a void inside the trench and extends upward. A diameter of a top end of the trench is smaller than a diameter of the insulating film.

In the preferred embodiment of the invention, the insulating film is formed of: a first insulating film which has a diameter increasing upward; and a second insulating film which surrounds the first insulating film and has a width decreasing upward.

A semiconductor device having trench isolation according to the second aspect of the invention includes a semiconductor substrate. A trench is provided on a surface of the semiconductor substrate. A silicon oxide film is formed on an inner wall of the trench. The silicon film is embedded into the trench with the silicon oxide film interposed. An insulating film is in contact with a surface of the silicon film and extends above the trench.

In a fabrication method of a semiconductor device having trench isolation, according to the third aspect of the invention, first of all, a mask film is formed on a semiconductor substrate. The mask film is etched so as to leave a desired region. A sidewall spacer is formed on a sidewall of the mask film left behind the etching. A surface of the semiconductor substrate is etched by using the mask film and the sidewall spacer as a mask to form a trench. An insulating film is formed on the semiconductor substrate so as to cover the top end portion of the trench while leaving a void inside the trench. The insulating film is etched back as far as to expose a surface of the mask film. The mask film is removed. Ion implantation is performed on the surface of the semiconductor substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device in a first step of the step sequence of a fabrication method of a semiconductor device according to a first embodiment;

FIG. 2 is a sectional view of a semiconductor device in a second step of the step sequence of the fabrication method of a semiconductor device according to a first embodiment;

FIG. 3 is a sectional view of a semiconductor device in a third step of the step sequence of the fabrication method of a semiconductor device according to a first embodiment;

FIG. 4 is a sectional view of a semiconductor device in a fourth step of the step sequence of the fabrication method of a semiconductor device according to a first embodiment;

FIG. 5 is a sectional view of a semiconductor device in a fifth step of the step sequence of the fabrication method of a semiconductor device according to a first embodiment;

FIG. 6 is a sectional view of a semiconductor device in a sixth step of the step sequence of the fabrication method of a semiconductor device according to a first embodiment;

FIG. 7 is a sectional view of a semiconductor device in a seventh step of the step sequence of the fabrication method of a semiconductor device according to a first embodiment;

FIG. 8 is a sectional view of a semiconductor device in an eighth step of the step sequence of the fabrication method of a semiconductor device according to a first embodiment;

FIG. 9 is a sectional view of a semiconductor device in a ninth step of the step sequence of the fabrication method of a semiconductor device according to a first embodiment;

FIG. 10 is a sectional view of a semiconductor device in a tenth step of the step sequence of the fabrication method of a semiconductor device according to a first embodiment;

FIG. 11 is a sectional view of a semiconductor device in an eleventh step of the step sequence of the fabrication method of a semiconductor device according to a first embodiment;

FIG. 12 is a sectional view of a semiconductor device in a twelfth step of the step sequence of the fabrication method of a semiconductor device according to a first embodiment;

FIG. 13 is a sectional view of a semiconductor device in a thirteenth step of the step sequence of the fabrication method of a semiconductor device according to a first embodiment;

FIG. 14 is a sectional view taken along a source to gate to drain direction in the device of FIG. 13;

FIG. 15 is a sectional view of a semiconductor device in a fourteenth step of the step sequence of the fabrication method of a semiconductor device according to a first embodiment;

FIG. 16 is a sectional view taken along a source to gate to drain direction in the device of FIG. 15;

FIG. 17 is a sectional view of a semiconductor device in a first step of the step sequence of a fabrication method of a semiconductor device according to a second embodiment;

FIG. 18 is a sectional view of a semiconductor device in a second step of the step sequence of the fabrication method of a semiconductor device according to a second embodiment;

FIG. 19 is a sectional view of a semiconductor device in a third step of the step sequence of the fabrication method of a semiconductor device according to a second embodiment;

FIG. 20 is a sectional view of a semiconductor device in a fourth step of the step sequence of the fabrication method of a semiconductor device according to a second embodiment;

FIG. 21 is a sectional view of a semiconductor device in a fifth step of the step sequence of the fabrication method of a semiconductor device according to a second embodiment;

FIG. 22 is a sectional view of a semiconductor device in a sixth step of the step sequence of the fabrication method of a semiconductor device according to a second embodiment;

FIG. 23 is a sectional view of a semiconductor device in a first step of the step sequence of a fabrication method of a semiconductor device according to a third embodiment;

FIG. 24 is a sectional view of a semiconductor device in a second step of the step sequence of the fabrication method of a semiconductor device according to a third embodiment;

FIG. 25 is a sectional view of a semiconductor device in a third step of the step sequence of the fabrication method of a semiconductor device according to a third embodiment;

FIG. 26 is a sectional view of a semiconductor device in a fourth step of the step sequence of the fabrication method of a semiconductor device according to a third embodiment;

FIG. 27 is a sectional view of a semiconductor device in a fifth step of the step sequence of the fabrication method of a semiconductor device according to a third embodiment;

FIG. 28 is a sectional view of a semiconductor device in a sixth step of the step sequence of the fabrication method of a semiconductor device according to a third embodiment;

FIG. 29 is a sectional view of a semiconductor device in a seventh step of the step sequence of the fabrication method of a semiconductor device according to a third embodiment;

FIG. 30 is a sectional view of a semiconductor device in a first step of the step sequence of a fabrication method of a semiconductor device according to a fourth embodiment;

FIG. 31 is a sectional view of a semiconductor device in a second step of the step sequence of the fabrication method of a semiconductor device according to a fourth embodiment;

FIG. 32 is a sectional view of a semiconductor device in a third step of the step sequence of the fabrication method of a semiconductor device according to a fourth embodiment;

FIG. 33 is a sectional view of a semiconductor device in a fourth step of the step sequence of the fabrication method of a semiconductor device according to a fourth embodiment;

FIG. 34 is a sectional view of a semiconductor device in a fifth step of the step sequence of a fabrication method of a semiconductor device according to a fifth embodiment;

FIG. 35 is a sectional view of a semiconductor device in a first step of the step sequence of the fabrication method of a semiconductor device according to a fifth embodiment;

FIG. 36 is a sectional view of a semiconductor device in a second step of the step sequence of the fabrication method of a semiconductor device according to a fifth embodiment;

FIG. 37 is a sectional view of a semiconductor device in a first step of the step sequence of a fabrication method of a semiconductor device according to a sixth embodiment;

FIG. 38 is a sectional view of a semiconductor device in a second step of the step sequence of the fabrication method of a semiconductor device according to a sixth embodiment;

FIG. 39 is a sectional view of a semiconductor device in a third step of the step sequence of the fabrication method of a semiconductor device according to a sixth embodiment;

FIG. 40 is a sectional view of a semiconductor device in a first step of the step sequence of a fabrication method for a prior art semiconductor device;

FIG. 41 is a sectional view of a semiconductor device in a second step of the step sequence of the fabrication method for a prior art semiconductor device;

FIG. 42 is a sectional view of a semiconductor device in a third step of the step sequence of the fabrication method for a prior art semiconductor device;

FIG. 43 is a sectional view of a semiconductor device in a fourth step of the step sequence of the fabrication method for a prior art semiconductor device;

FIG. 44 is a sectional view of a semiconductor device in a fifth step of the step sequence of the fabrication method for a prior art semiconductor device;

FIG. 45 is a sectional view of a semiconductor device in a sixth step of the step sequence of the fabrication method for a prior art semiconductor device; and

FIG. 46 is a sectional view of a semiconductor device in a seventh step of the step sequence of the fabrication method for a prior art semiconductor device.

### DESCRIPTION OF PREFERRED EMBODIMENTS

Description will be given of embodiments of the present invention below.

### First Embodiment

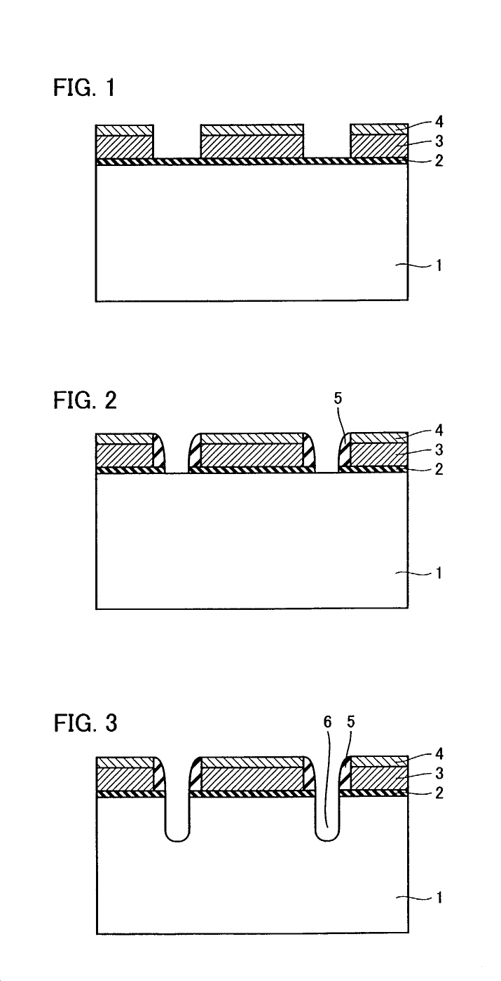

Referring to FIG. 1, a silicon oxide film 2 is formed on a semiconductor substrate 1 to a thickness, for example, in the range of from 5 to 10 nm by a thermal oxidation method or a CVD method. Thereafter, a first mask film 3, for example a silicon film, is formed to a thickness, for example, in the range of 100 to 300 nm by a CVD method. Subsequent to this, a second mask film 4, for example a silicon nitride film, is formed to a film thickness of from 50 to 150 nm. The mask film 3 may be a silicon germanium film instead of a silicon film.

Referring to FIG. 2, a silicon oxide film, which is a material different from second mask film 4, is formed to a thickness, for example, in the range of from 10 to 50 nm, by a CVD method. Then anisotropic etching is applied on the silicon oxide film to form a sidewall spacer 5. A film thickness thereof formed at this time is adjusted to be one half the width of trench 6 or less.

Referring to FIG. 3, semiconductor substrate 1 is etched with sidewall spacer 5, second mask film 4 and first mask film 3 as a mask to form a trench 6 of a depth, for example, in the range of from 200 to 400 nm.

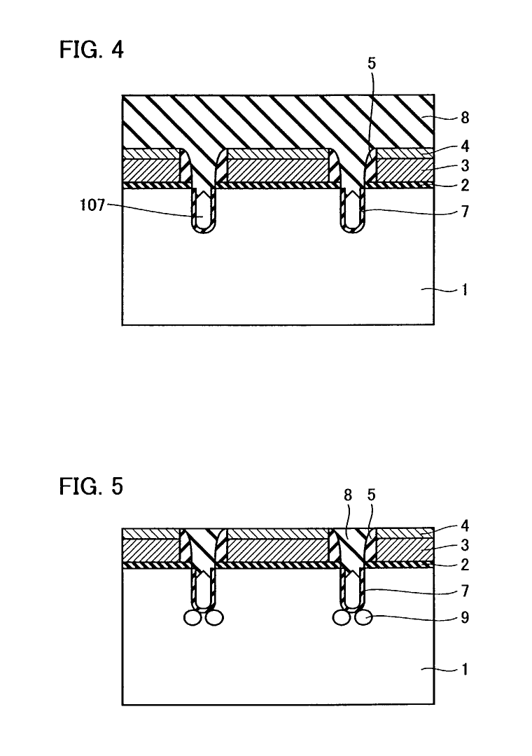

Referring to FIG. 4, a thermal oxide film 7 is lined on the surface of trench 6 to a thickness, for example, in the range of from 5 to 20 nm by a thermal oxidation method. Thereafter, an insulating film 8 is formed to a thickness, for example, in the range of 300 to 800 nm by a CVD method, a sputtering method or a sol gel method to fill a top portion of trench 6. At this time, no necessity arises for filing the interior of trench 8 to the full, but the top end portion of trench 6 has only to be covered. In the figure, a void 107 is formed. By forming the void, relaxation of a stress is enabled.

Referring to FIG. 5, a film thickness of an insulating film 8 is reduced by an etch back method or a CMP method as far as to expose a surface of second mask film 4 to plug the top end portion of trench 6. Thereafter, a channel cut 9 is formed by an ion implantation method through the surface. While a void is formed in trench 6, semiconductor substrate 1 is present below sidewall spacer 5 and an implantation profile can be correctly predicted. That is, channel cut 9 can be formed without receiving any influence of void 107 in trench 6.

Through the steps described above, trench isolation is completed. Thereafter, a transistor is formed. Description will be given of a process forming a transistor using the isolation below.

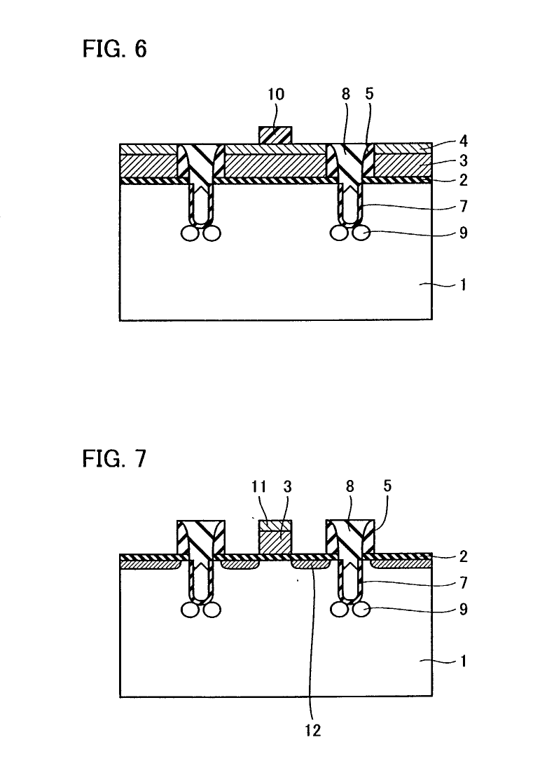

Referring to FIG. 6, a photoresist 10 defining a gate pattern is formed by a lithographic technique.

Referring to FIG. 7, by an etching method, gate pattern 11 is formed. Thereafter, by an ion implantation method, for example, boron in a case of PMOS (P channel Metal Oxide Semiconductor) or, arsenic or phosphorus in a case of NMOS (N channel Metal Oxide Semiconductor) is implanted at a dose in the range of from 1×10¹⁴ to 1×10¹⁵ cm⁻² to form first impurity diffusion regions 12.

Referring to FIG. 8, an insulating film, for example a silicon oxide film or a silicon nitride film, or a stacked film thereof is formed to a thickness in the range of from 20 to 60 nm by a CVD method to form a sidewall spacer 13 by an etch back method. Thereafter, by an ion implantation method, for example, boron in a case of PMOS or, arsenic or phosphorus in a case of NMOS is implanted at a dose in the range of from 1×10¹⁵ to 1×10¹⁶ cm⁻² to form second impurity diffusion regions 14.

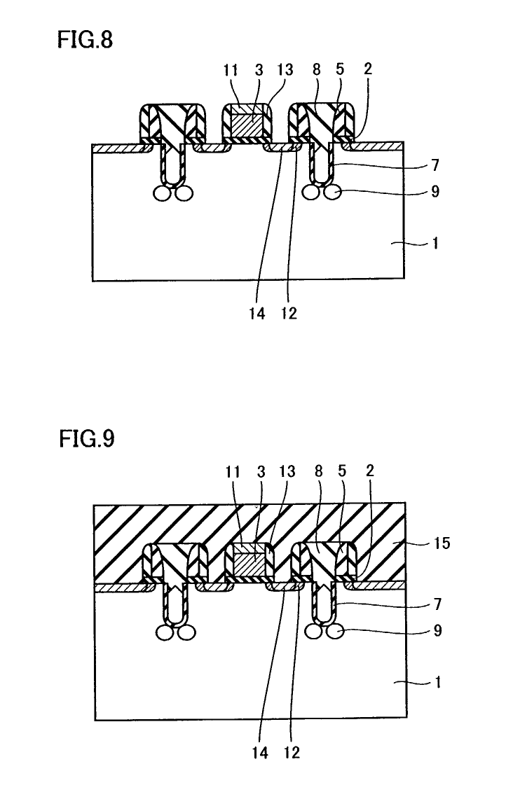

Referring to FIG. 9, an insulating film 15, for example a silicon oxide film, is formed to a thickness in the range of from 400 to 1000 nm by a CVD method.

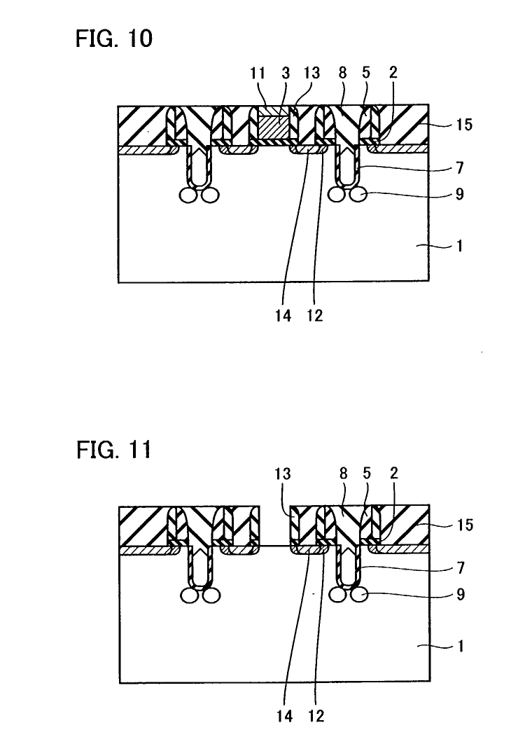

Referring to FIGS. 9 and 10, insulating film 15 is etched back by a CMP method or an etch back method to expose the surface of second mask film 4.

Referring to FIG. 11, second mask film 4, first mask film 3 and oxide film 2 are removed by a wet etching method or a dry etching method.

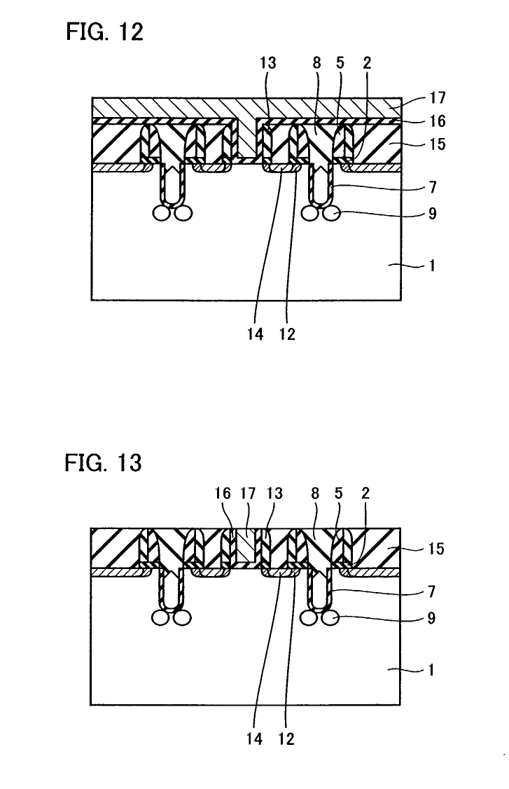

Referring to FIG. 12, a gate insulating film 16, for example an aluminum oxide film, a hafnium oxide film, a zirconium oxide film, a silicon oxide film or a silicon nitride film, is formed to a thickness of in the range of from 1 to 20 nm, followed by formation of a conductive film 17, for example a polycrystalline silicon film, a metal silicide film, a metal nitride film, a metal silicon nitride film, a metal film or a stacked film thereof to a thickness in the range of 100 to 500 nm.

Referring to FIG. 13, conductive film 17 is left only in a gate electrode region by a CMP method and an etch back method.

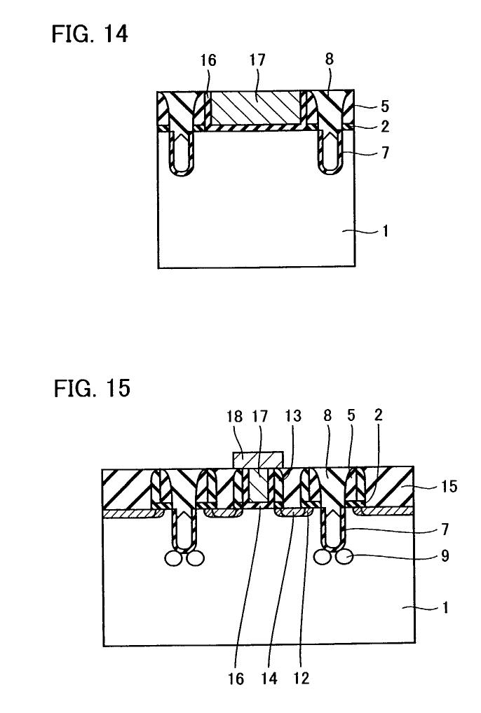

FIG. 14 is a sectional view taken along a direction perpendicular to a direction along which source, gate and drain are arranged in the step of FIG. 13.

Referring to FIG. 15, a conductive film, for example a TiN, W or AlCu film or a stacked film thereof is formed to a thickness in the range of from 50 to 200 nm and the film is patterned by a photolithographic technique or an etching method to form an interconnect.

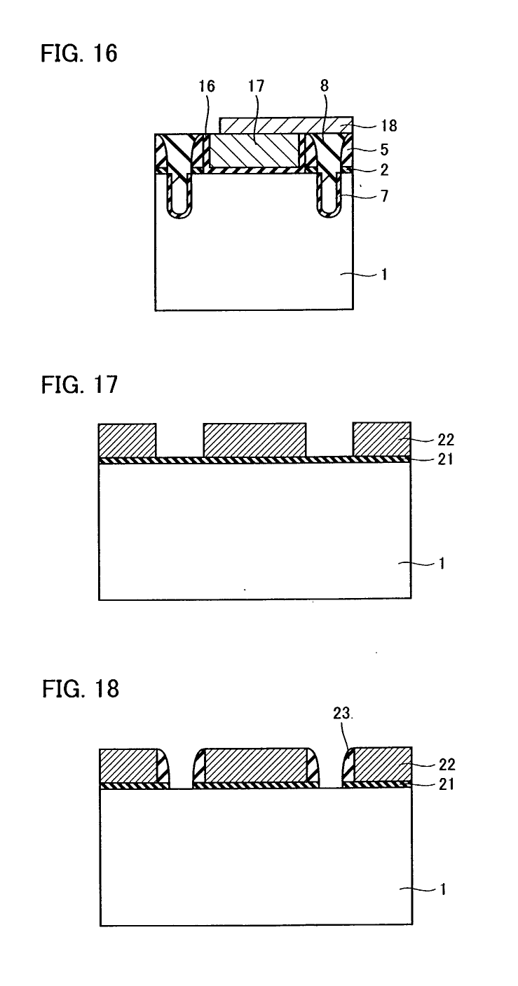

FIG. 16 is a sectional view taken along a direction perpendicular to a direction along which source, gate and drain are arranged in the step of FIG. 15. According to the above process, a MISFET (Metal-Insulator Semiconductor Field Effect Transistor) is completed.

According to this embodiment, referring to FIGS. 2, 3 and 4, an offset region (a width of sidewall 5) is provided in isolation region (6) to form a trench (6) in a region surrounded with the offset region and to form a cavity 107 in the interior of the trench. Not only can a stress is relaxed with cavity 107 provided in the interior of the trench, but also channel cut layer 9 can be formed under good control with an offset region provided, thereby enabling achievement of a good isolation characteristic.

### Second Embodiment

In the first embodiment, a silicon film is used as a first mask. In this embodiment, no first mask film is used.

Referring to FIG. 17, an underlying film 21 is formed using a silicon oxide film on a semiconductor substrate 1 to a film thickness in the range of from 10 to 20 nm by a thermal oxidation method or a CVD method. Thereafter, a silicon nitride film 22 is formed by a CVD method. Subsequent to this, a desired pattern of the films is formed by a photolithographic technique and an etching method.

Referring to FIG. 18, a silicon oxide film is formed to a thickness, for example, in the range of from 10 to 50 nm by a CVD method and anisotropic etching is applied to the silicon film to thereby form a sidewall spacer 23.

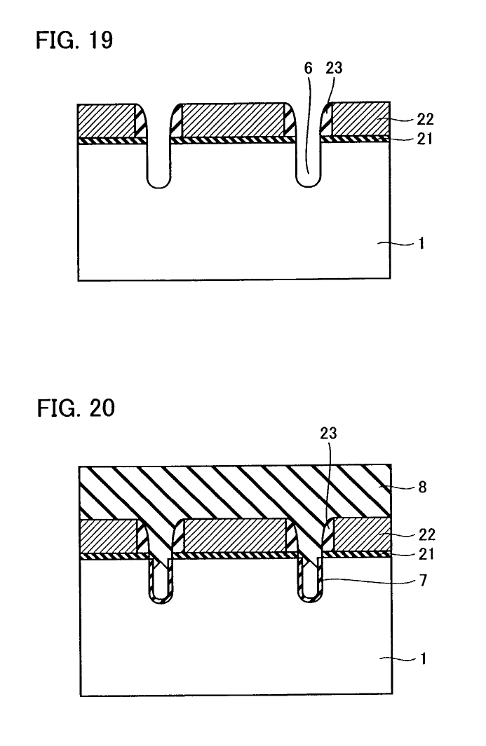

Referring to FIG. 19, semiconductor substrate 1 is etched with silicon nitride film 22 and sidewall spacer 23 as a mask to form trench 6.

Referring to FIG. 20, thermal oxide film 7 is formed on the surface of trench 6 to a thickness, for example, in the range of from 5 to 20 nm by a thermal oxidation method. Then, insulating film 8 is formed to a thickness, for example, in the range of from 300 to 800 nm by a CVD method to fill a top portion of trench 6. At this time, no necessity arises for filling the interior of trench 8 to the full, but the top end portion of trench 6 has only to be covered.

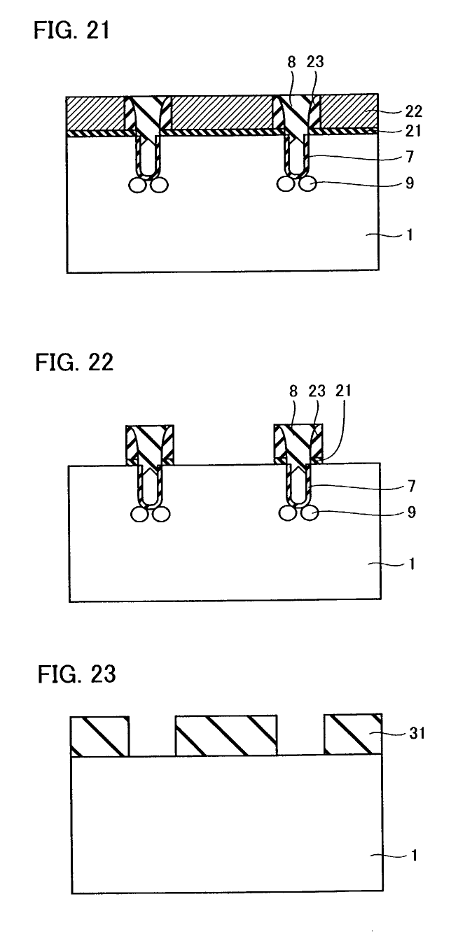

Referring to FIGS. 20 and 21, a film thickness of insulating film 8 is reduced as far as to expose the surface of silicon nitride film 22 by an etch back method or a CMP method to plug the top end portion of trench 6. Thereafter, channel cut 9 is formed through the surface by an ion implantation method.

Referring to FIG. 22, silicon nitride film 22 is selectively removed by a wet etching using hot phosphoric acid. At this time, while part of underlying film 21 is exposed, the film may be removed by cleaning with hydrofluoric acid or the like.

Thereafter, in order to form a gate electrode, a gate insulating film, which is a silicon oxide film, a silicon nitride film or a metal oxide film, is formed by a CVD method and subsequent to this, silicon, silicon germanium, metal silicide or the like is formed by a CVD method to pattern.

In such an embodiment as well, an effect similar to that of the first embodiment is exerted.

### Third Embodiment

A silicon nitride film may be used as an insulating film formed on a trench. By forming an interlayer insulating film formed on a transistor with a silicon oxide film, borderless contact with silicon substrate is enabled.

Referring to FIG. 23, a silicon oxide film 31 is formed on a semiconductor substrate 1 to a thickness, for example, in the range of from 200 to 300 nm by a CVD method. Thereafter, a desired pattern is formed thereon by a photolithographic technique and an etching method.

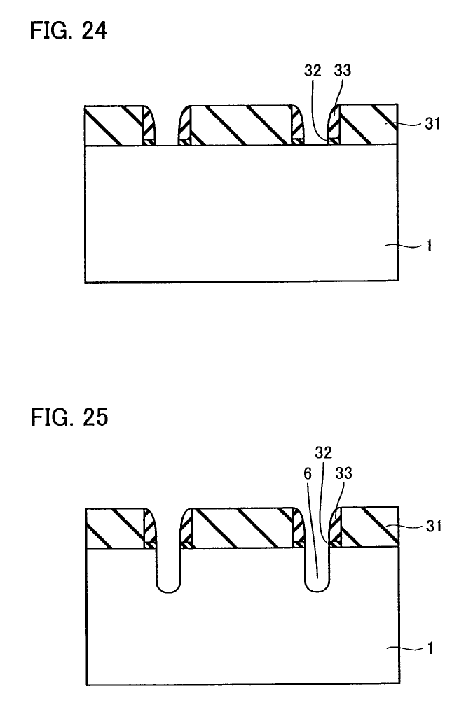

Referring to FIG. 24, a silicon nitride film is formed to a thickness, for example, in the range of from 10 to 50 nm by a CVD method and anisotropic etching is applied to the film to form a sidewall spacer 33. Note that before formation of the silicon nitride film, a silicon oxide film 32 is formed to a thickness, for example, in the range of from 5 to 10 nm by a thermal oxidation method and a CVD method. With silicon oxide film 32 formed, it is prevented from occurring that an unnecessary interface state is formed at the interface with silicon substrate, thereby enabling prevention of deterioration in isolation characteristic.

Referring to FIG. 25, etching is performed with sidewall spacer 33 and silicon oxide film 31 as a mask to form trench 6.

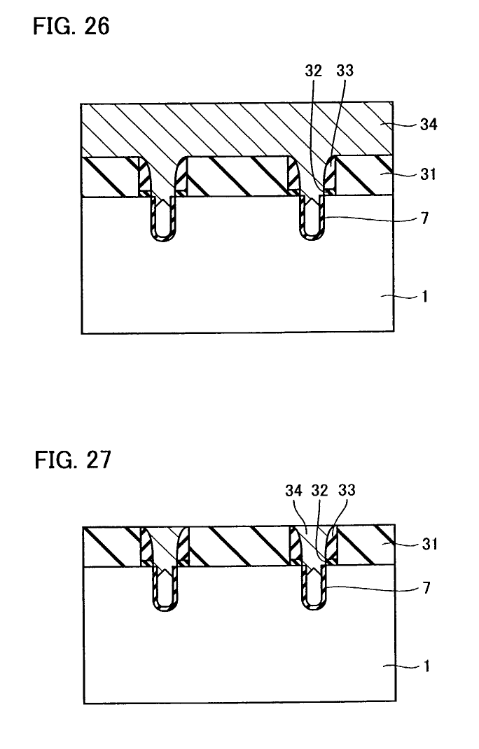

Referring to FIG. 26, thermal oxide film 7 is formed on the surface of trench 6 to a thickness, for example, in the range of from 5 to 20 nm by a thermal oxidation method. Thereafter, a silicon nitride film 34 is formed to a thickness, for example, in the range of from 300 to 800 nm by a CVD method to fill the top portion of trench 6.

Referring to FIG. 27, silicon nitride film 34 is etched by a CMP method or an etch back method to expose silicon oxide film 31 and to planarize the surface.

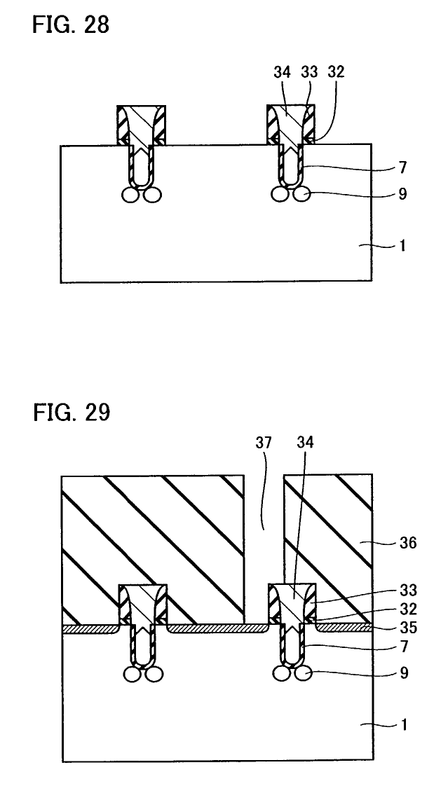

Referring to FIG. 28, channel cut 9 is formed by an ion implantation method. Thereafter, silicon oxide film 31 is removed with a hydrofluoric acid solution.

By forming a silicon nitride film in an element isolation region in such a manner, formation of a self-alignment contact is enabled.

For example, an impurity region 35 is formed by an ion implantation method and an anneal method, followed by formation of a silicon oxide film 36 by a CVD method. Thereafter, a contact hole 37 is formed in silicon oxide film 36 by a lithographic technique and an etching method. Since silicon oxide film 36 can be selectively etched relatively to silicon nitride film 34, a hole has no chance to reach trench 6 even when a hole opening portion is shifted to an element isolation insulating film side as shown in FIG. 29.

For this reason, a margin for overlapping in photolithography can be smaller, leading to easy microfabrication.

### Fourth Embodiment

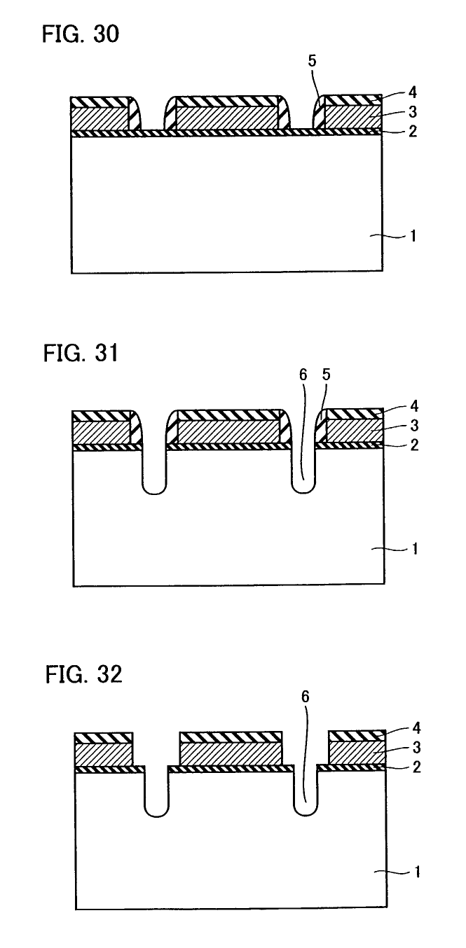

Referring to FIG. 30, silicon oxide film 2 is formed on semiconductor substrate 1 to a thickness, for example, in the range of from 5 to 10 nm by a thermal oxidation or a CVD method. Thereafter, first mask film 3, for example a silicon film, is formed to a thickness in the range of from 100 to 300 nm by a CVD method. Subsequent to this, second mask film 4, for example a silicon nitride film, is formed to a thickness in the range of from 50 to 150 nm. Mask oxide film 3 may be a silicon germanium film in stead of a silicon film. Then, a silicon oxide film, which is a material different from second mask film 4, is formed to a thickness, for example, in the range of from 10 to 50 nm by a CVD method. Then, sidewall spacer 5 is formed by anisotropic etching. A thickness thereof formed at this time is one half the width of a trench or less.

Referring to FIG. 31, semiconductor substrate 1 is etched with sidewall spacer 5, second mask film 4 and first mask film 3 as a mask to form trench 6 of a depth, for example, in the range of from 200 to 400 nm.

A process so far is similar to the process from FIG. 1 to 3 of the first embodiment.

Referring to FIGS. 31 and 32, sidewall spacer 5 is then selectively removed by a wet etching with hydrofluoric acid or the like or dry etching.

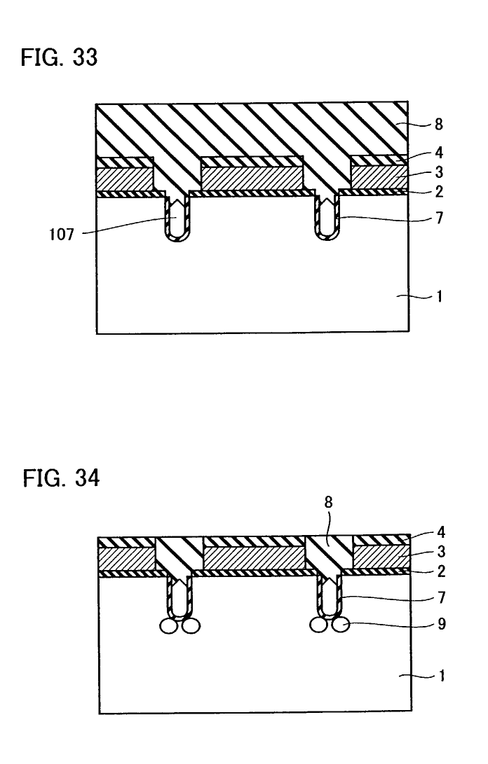

Referring to FIG. 33, thermal oxide film 7 is formed on the surface of trench 6 to a thickness, for example, in the range of from 5 to 20 nm by a thermal oxidation method. Thereafter, insulating film 8 is formed to a thickness, for example, in the range of from 300 to 800 nm by a CVD method, a sputtering method, a sol-gel method or the like to fill the top portion of trench 6. At this time, no necessity arises for filling the interior of trench 8 to the full, but the top end portion of trench 6 has only to be covered. In the figure, a void 107 is formed.

Referring to FIG. 34, a thickness of insulating film 8 is reduced as far as to expose the surface of second mask film 4 by an etch back method or a CMP method to plug the top portion of trench 6. Thereafter, ions are implanted through the surface to form channel cut 9.

According to this embodiment, since sidewall spacer 5 is removed, filling with insulating film 8 is easier compared with the first embodiment.

Note that an example modification may be adopted that after passing through the steps from FIG. 17 to FIG. 18, sidewall spacer is removed, followed by the same process as in this embodiment. Thereby, a structure of a mask film becomes simply, resulting in a simpler process.

### Fifth Embodiment

In the fourth embodiment, after formation of trench 6, sidewall spacer 5 is removed.

In this embodiment, on formation of trench 6, sidewall 5 is removed, thereby providing a process that enables simplification of steps.

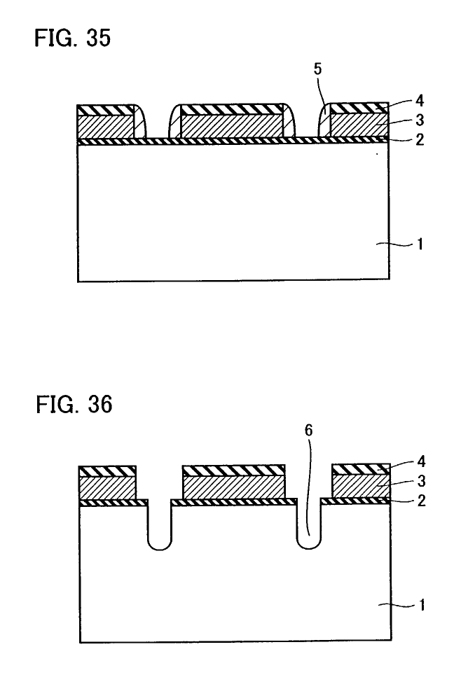

Referring to FIG. 35, in the step of FIG. 30 in the fourth embodiment, sidewall spacer 5 is formed using, for example, polycrystalline silicon or amorphous silicon by a CVD method. Thereafter, anisotropic etching is applied to form sidewall spacer 5.

Referring to FIGS. 35 and 36, oxide film 2 is etched with sidewall spacer 5 and second mask film 4 as a mask. In succession thereafter, sidewall spacer 5 and semiconductor substrate 1 are etched not only to form trench 6 but also to remove sidewall spacer 5.

Thereafter, similar to the steps of FIGS. 33 and 34, insulating film 8 is formed on trench 6. By forming sidewall spacer 5 with the same material as substrate 1 as described above, not only can trench 6 be formed, but sidewall spacer 5 can also be removed, which enables reduction of steps.

Furthermore, as an example modification, a process may be adopted that instead of the steps of FIGS. 17 and 18, sidewall spacer 5 is formed using silicon material and thereafter, the same steps as in this embodiment are passed through.

### Sixth Embodiment

In the above process, insulating film 8 is planarized and a void is formed in the interior of a trench 60. Silicon, which is the same material as a substrate may fill the interior of a trench.

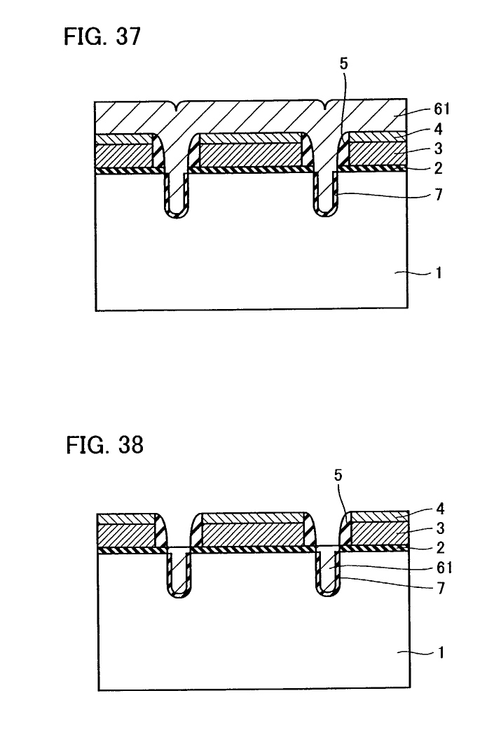

Referring to FIG. 37, after the step shown in FIG. 3, thermal oxide film 7 is formed on the sidewall of a trench by a thermal oxidation method. Thereafter, silicon film 61 is formed to a thickness, for example, in the range of from 200 to 300 nm. The thickness is determined by a width of trench 6.

Then, referring to FIG. 38, a film thickness of silicon film 61 is reduced by an etch back method to fill silicon film 61 in the interior of trench 61. Since substrate 1 and filling film 61 are of the same material as each other, it can be prevented from occurring that a stress is generated by thermal expansion.

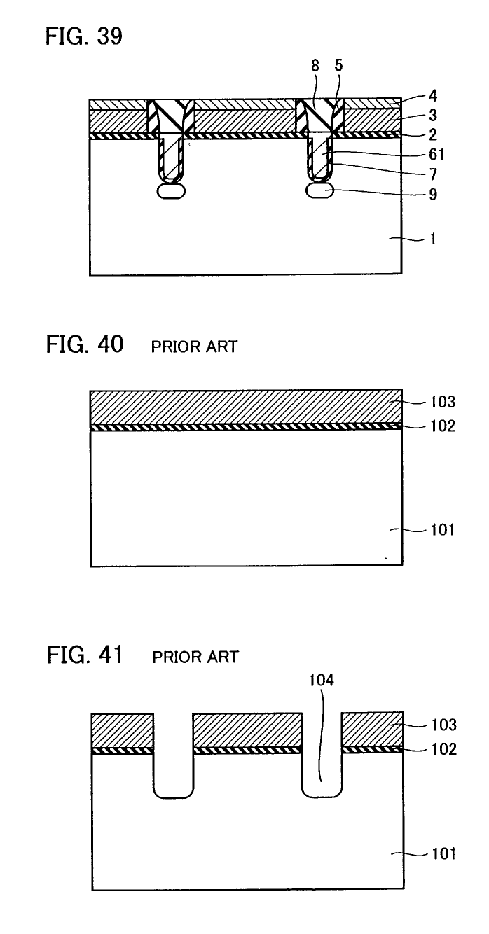

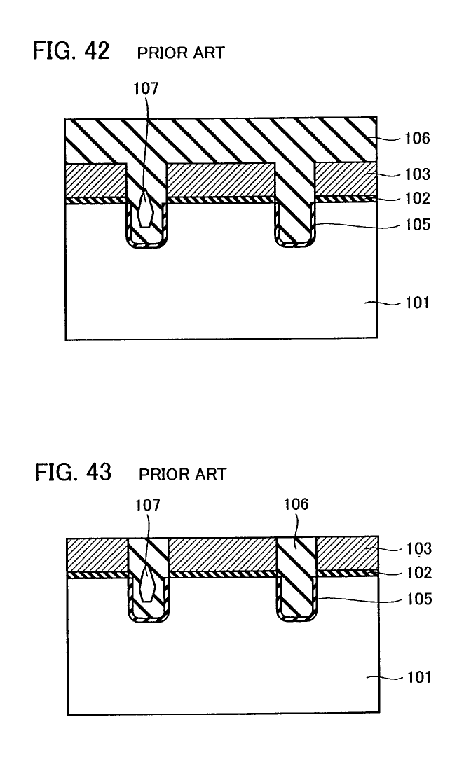

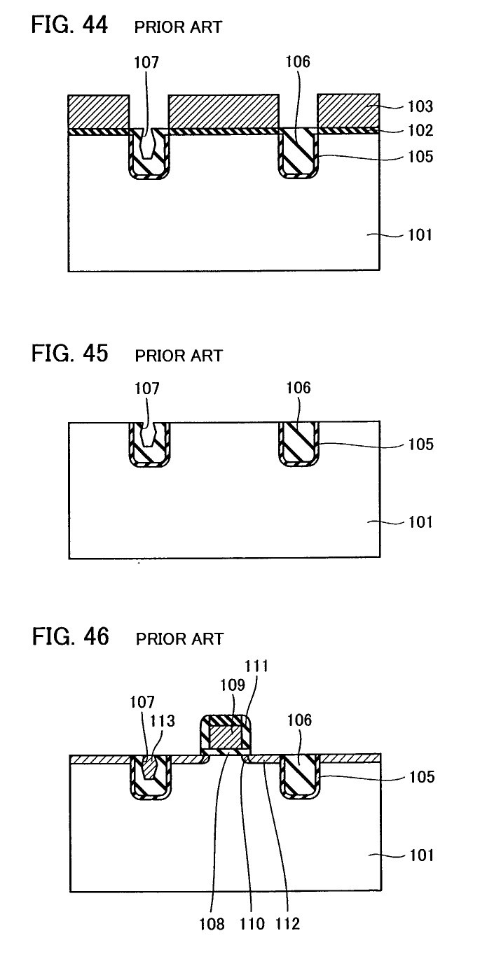

Referring to FIG. 39, insulating film 8, for example a silicon oxide film, is formed so as to fill a recess by a CVD method and thereafter, the surface is planarized by a CMP method or an etch back method.

Since silicon CVD is of good coverage, easy filling of the interior of a trench is effected. Furthermore, since insulating film 8 is formed on silicon oxide film 61 filling the interior of a trench, easy filling of a recess is effected. Thereafter, channel cut 9 is formed.

Furthermore, in this embodiment as well, as an example modification, a process may be adopted that after the steps from FIG. 17 to FIG. 18 are passed through, a silicon film fills the interior of trench 6 by the above process.

Furthermore, in all of the above embodiments, a trench width may be set at a prescribed value or less. In a case where a trench width is wide, it is difficult to leave an insulating film on the top portion of a trench. In such a case, in order to form a void in a trench, an aspect ratio of the trench is effectively set large. For example, in a case where a trench is of a rectangular shape consisting of a longer side and a shorter side in a plan view, a length of the shorter side is preferably 500 nm or less.

The embodiments disclosed this time should be understood to be presented by way of illustration but not by way of limitation in all aspects. It is intended that the scope of the present invention is shown not by the above descriptions but by the claims and the present invention includes the claims, a scope equivalent thereto and all modifications or alterations in the claims.

According to the present invention, as described above, the effect is exerted that provides a highly integrated semiconductor device capable of realizing a good isolation characteristic.

Although the present invention has been described and illustrated in detail, it is clearly understood that the same is by way of illustration and example only and is not to be taken by way of limitation, the spirit and scope of the present invention being limited by the terms of the appended claims.

What is claimed is:

1. A semiconductor device having trench isolation comprising:
a semiconductor substrate;
a trench provided on a surface of said semiconductor substrate; and
an insulating film that a part thereof fits into the trench so as to form a void inside said trench and extends upward, wherein
a diameter of a top end of said trench is smaller than a diameter of said insulating layer.

2. The semiconductor device having trench isolation according to claim 1, wherein said insulating film includes a silicon oxide film.

3. The semiconductor device having trench isolation according to claim 1, said insulating film includes a silicon nitride film.

4. The semiconductor device having trench isolation according to claim 1, wherein said insulating film is formed of: a first insulating film which has a diameter increasing upward; and a second insulating film which surrounds the first insulating film and has a width decreasing upward.

5. The semiconductor device having trench isolation according to claim 4, wherein said first and second insulating films are formed by a silicon oxide film.

6. The semiconductor device having trench isolation according to claim 4, wherein said first and second insulating films are formed by a silicon nitride film.

7. A semiconductor device having trench isolation comprising:
a semiconductor substrate;
a trench formed on a surface of said semiconductor;
a silicon oxide film formed on an inner wall of said trench;
a silicon film embedded into said trench with said silicon oxide film interposed; and
an insulating film being in contact with a surface of said silicon film and extending above the trench.

8. A fabrication method of a semiconductor device having trench isolation comprising the steps of:
forming a mask film on a semiconductor substrate;
etching said mask film so as to leave a desired region;
forming a sidewall spacer on a sidewall of the mask film left behind said etching;
etching a surface of said semiconductor substrate by using said mask film and said sidewall spacer as a mask to form a trench;
forming an insulating film on said semiconductor substrate so as to cover a top end portion of said trench while leaving a void inside the trench;
etching back said insulating film as far as to expose a surface of said mask film;
removing said mask film; and
performing ion implantation on the surface of said semiconductor substrate.

9. The fabrication method of the semiconductor device having trench isolation according to claim 8, further comprising a step of removing said mask film, and then forming an impurity diffusion layer under said sidewall spacer and in a depth which is approximately same depth as a bottom portion of said trench.

10. The fabrication method of the semiconductor device having trench isolation according to claim 8, wherein said mask film is a lamination film formed of a silicon oxide film, and silicon film and a silicon nitride film.

11. The fabrication method of the semiconductor device having trench isolation according to claim 8, wherein said mask film is a lamination film formed of a silicon oxide film and a silicon nitride film.
